(19) United States
(12) Patent Application Publication
(10) Pub. No.: US 2017/0352581 A1
(43) Pub. Date: Dec. 7, 2017

(54) SEMICONDUCTOR WAFER AND METHOD FOR MANUFACTURING THE SAME

(71) Applicant: Renesas Electronics Corporation, Tokyo (JP)

(72) Inventors: Makoto NISHIDA, Hitachinaka-shi (JP); Takuya FUJII, Hitachinaka-shi (JP)

(73) Assignee: Renesas Electronics Corporation, Tokyo (JP)

(21) Appl. No.: 15/614,946

(22) Filed: Jun. 6, 2017

(30) Foreign Application Priority Data
Jun. 7, 2016 (JP) 2016-113472

(51) Int. Cl. H01L 21/762; H01L 21/311; H01L 21/687

(52) U.S. Cl. CPC H01L 21/7624; H01L 21/68735; H01L 21/31111; H01L 21/31116

(57) ABSTRACT

A semiconductor wafer in accordance with an embodiment includes: a support substrate semiconductor wafer having a first surface and a second surface opposite to the first surface; and an active layer formed on the first surface. The support substrate semiconductor wafer includes a support substrate semiconductor and an insulating film which is formed on a first surface side and a second surface side of the support substrate semiconductor. An area of the insulating film of the second surface is smaller than an area of the insulating film of the first surface.

This nonprovisional application is based on Japanese Patent Application No. 2016-113472 filed on Jun. 7, 2016 with the Japan Patent Office, the entire contents of which are hereby incorporated by reference.

### BACKGROUND OF THE INVENTION

### Field of the Invention

The present invention relates to a semiconductor wafer and a method for manufacturing the same, and particularly relates to an SOI (Silicon On Insulator) wafer and a method for manufacturing the same.

### Description of the Background Art

A conventional SOI wafer includes a semiconductor wafer to be used as a support substrate (hereinafter support substrate semiconductor wafer), and an active layer. The support substrate semiconductor wafer has a first surface and a second surface which is an opposite surface to the first surface. The support substrate semiconductor wafer includes a support substrate semiconductor and an insulating film. The insulating film is formed on a first surface side and a second surface side of the support substrate semiconductor water. The active layer is formed on the first surface of the support substrate semiconductor wafer.

In the process of forming a semiconductor device on the SOI wafer, the SOI water is exposed to plasma in an ion implantation step, a dry etching step, or the like, for example. As a result, the support substrate semiconductor wafer is charged to cause the second surface of the SOI wafer to be adsorbed to a work stage, a transport arm, or the like (electrostatic adsorption phenomenon). When the electrostatic adsorption phenomenon occurs, a resultant problem is that the SOI wafer cannot be transported from the work stage, the transport arm, or the like.

As a structure of the SOI wafer for addressing such an electrostatic adsorption phenomenon, the structure disclosed in Japanese Patent Laying-Open No. 2013-98436 and the structure disclosed in Japanese Patent Laying-Open No. 2013-98435 have been proposed.

In the structure disclosed in Japanese Patent Laying-Open No. 2013-98436, a conductive film is formed on the second surface of the support substrate semiconductor wafer. In the structure disclosed in Japanese Patent Laying-Open No. 2013-98435, the lateral side surface of the support substrate semiconductor wafer is polished to expose the support substrate semiconductor.

### SUMMARY OF THE INVENTION

Regarding the structure disclosed in Japanese Patent Laying-Open No. 2013-98436, the film is newly formed on the second surface of the support substrate semiconductor wafer, and therefore, the support substrate semiconductor wafer may be warped. Regarding the structure disclosed in Japanese Patent Laying-Open No. 2013-98435, the lateral side surface of the support substrate semiconductor wafer is polished to expose the support substrate semiconductor, which complicates the work process.

Other problems and new characteristics will be apparent from the description herein and the accompanying drawings.

A semiconductor wafer in accordance with an embodiment includes: a support substrate semiconductor wafer having a first surface and a second surface opposite to the first surface; and an active layer formed on the first surface. The support substrate semiconductor wafer includes a support substrate semiconductor and an insulating film which is formed on a first surface side and a second surface side of the support substrate semiconductor. An area of the insulating film of the second surface is smaller than an area of the insulating film of the first surface.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a semiconductor wafer in accordance with an embodiment, as seen from a first surface of the semiconductor wafer.

FIG. 2 is a cross-sectional view of a semiconductor wafer in accordance with an embodiment.

FIG. 3 is a cross-sectional view of a semiconductor wafer in accordance with a first modification of the embodiment.

FIG. 4 is a cross-sectional view of a semiconductor wafer in accordance with a second modification of the embodiment.

FIG. 5 is a cross-sectional view of a semiconductor wafer in accordance with a third modification of the embodiment.

FIG. 6A is a first example of a top view of a partially enlarged second surface of a semiconductor wafer in accordance with an embodiment.

FIG. 6B is a second example of a top view of a partially enlarged second surface of a semiconductor wafer in accordance with an embodiment.

FIG. 6C is a third example of a top view of a partially enlarged second surface of a semiconductor wafer in accordance with an embodiment.

FIG. 6D is a fourth example of a top view of a partially enlarged second surface of a semiconductor wafer in accordance with an embodiment.

FIG. 7A is a first example of a top view of a partially enlarged second surface of a semiconductor wafer in accordance with a fourth modification of the embodiment.

FIG. 7B is a second example of a top view of a partially enlarged second surface of a semiconductor wafer in accordance with the fourth modification of the embodiment.

FIG. 7C is a third example of a top view of a partially enlarged second surface of a semiconductor wafer in accordance with the fourth modification of the embodiment.

FIG. 8A is a first example of a top view of a partially enlarged second surface of a semiconductor wafer in accordance with a fifth modification of the embodiment.

FIG. 8B is a second example of a top view of a partially enlarged second surface of a semiconductor wafer in accordance with the fifth modification of the embodiment.

FIG. 9 is a top view showing the whole of a second surface of a semiconductor water in accordance with an embodiment.

FIG. 10 is a process chart of a method for manufacturing a semiconductor wafer in accordance with an embodiment.

FIG. 11 is a cross-sectional view of a semiconductor wafer in accordance with an embodiment, in a step for forming a support substrate semiconductor wafer.

FIG. 12A is a cross-sectional view of the semiconductor wafer in accordance with an embodiment, after a semiconductor wafer for an active layer is bonded in a step for forming an active layer.

FIG. 12B is a cross-sectional view of the semiconductor wafer in accordance with an embodiment, after the bonded semiconductor wafer for an active layer is polished in the step for forming an active layer.

FIG. 13 is a cross-sectional view of the semiconductor wafer in accordance with an embodiment, in a step for forming a protective layer.

FIG. 14A is a cross-sectional view of the semiconductor wafer in accordance with an embodiment, in a step for forming a mask.

FIG. 14B is a cross-sectional view of the semiconductor wafer in accordance with an embodiment, in a step for patterning the mask.

FIG. 14C is a first example of a cross-sectional view of the semiconductor wafer in accordance with an embodiment, in an etching step.

FIG. 14D is a second example of a cross-sectional view of the semiconductor wafer in accordance with an embodiment, in the etching step.

FIG. 15 is a cross-sectional view of the semiconductor wafer in accordance with an embodiment, in the etching step.

FIG. 16 is a cross-sectional view of the semiconductor wafer in accordance with an embodiment, in a recess forming step.

FIG. 17A is a cross-sectional view of a semiconductor wafer in accordance with an embodiment, after a conductive film is formed in a step for forming a conductive film.

FIG. 17B is a cross-sectional view of the semiconductor wafer in accordance with an embodiment, after removal of the conductive film protruding from the recess formed in the step for forming a conductive film.

FIG. 17C is another example cross-sectional view of a semiconductor device in accordance with an embodiment, in the step for forming a conductive film.

FIG. 18 is a cross-sectional view of a semiconductor wafer in accordance with a comparative example.

FIG. 19A is a schematic diagram showing a mechanism of causing a semiconductor wafer to be adsorbed to a work stage in the comparative example.

FIG. 19B is a schematic diagram showing a mechanism of causing a semiconductor wafer to be adsorbed to work stage in an embodiment.

FIG. 20 is a schematic diagram showing a mechanism of warp of a semiconductor wafer in accordance with an embodiment.

### DESCRIPTION OF THE PREFERRED EMBODIMENTS

In the following, embodiments will be described with reference to the drawings. In the drawings, the same or corresponding parts are denoted by the same reference characters. Embodiments as described below may at least partially be combined.

A structure of a semiconductor wafer in accordance with an embodiment will hereinafter be described.

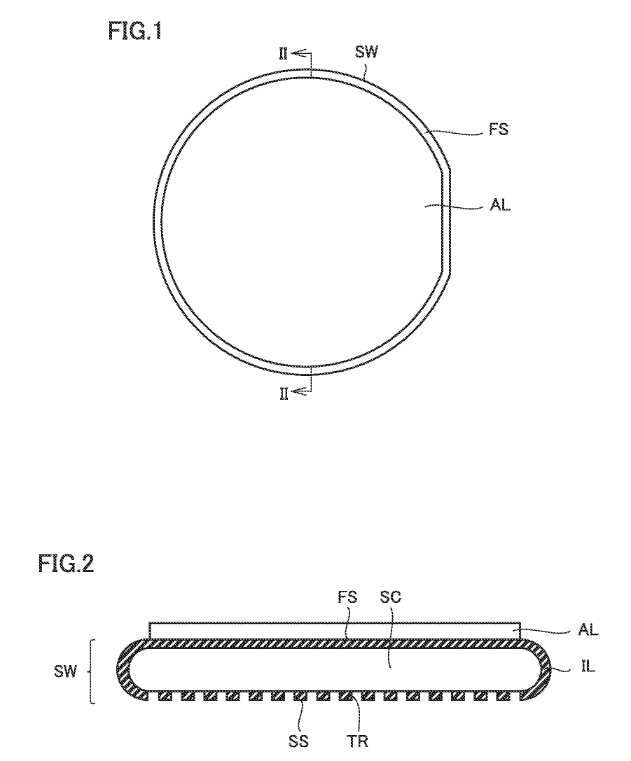

As shown in FIG. 1, the semiconductor wafer in accordance with the embodiment includes a support substrate semiconductor wafer SW and an active layer AL.

Support substrate semiconductor wafer SW has a first surface FS and a second surface SS (see FIG. 2). Second surface SS is an opposite surface to first surface FS. Active layer AL is formed on first surface FS. For active layer AL, a single crystal of silicon (Si) for example is used. On active layer AL, a semiconductor device is formed.

As shown in FIG. 2, support substrate semiconductor wafer SW includes a support substrate semiconductor SC and an insulating film IL. Insulating film IL is formed on a first surface FS side and a second surface SS side of support substrate semiconductor SC. For support substrate semiconductor SC, a single crystal of Si for example is used. For insulating film IL, silicon dioxide (SiO₂) for example is used.

The area of insulating film IL of second surface SS is smaller than the area of insulating film IL of first surface FS. The area of insulating film IL of second surface SS is preferably 0.5 times or more and less than once as large as the area of insulating film IL of first surface FS.

Specifically, in insulating film IL formed on the second surface SS side, a recess TR for example is formed. In the portion where recess TR is formed, no insulating film IL of second surface SS is present. Accordingly, recess TR makes the area of insulating film IL of second surface SS smaller than the area of insulating film IL of first surface FS.

Recess TR extends through insulating film IL formed on the second surface SS side, for example. Namely, recess TR reaches support substrate semiconductor SC. Thus, support substrate semiconductor SC is exposed from recess TR.

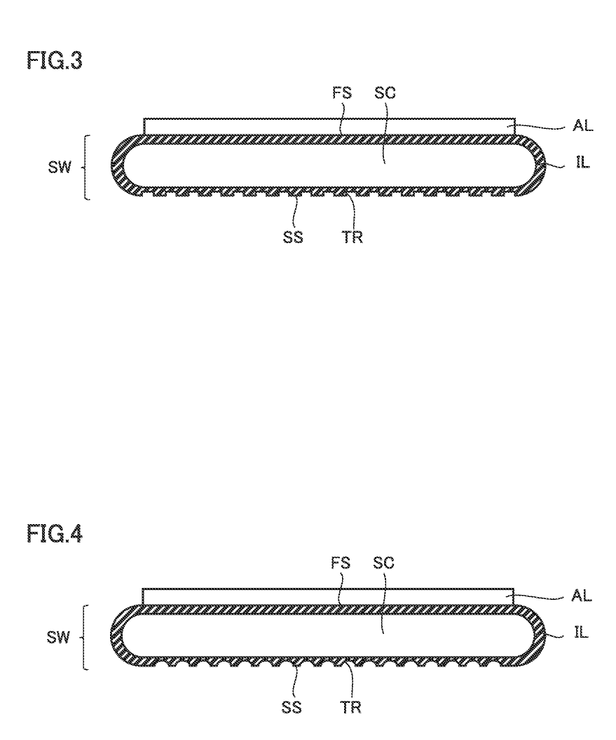

The form of recess TR is not limited to this. As shown in FIG. 3, recess TR may not extend through insulating film IL. Namely, support substrate semiconductor SC may not be exposed from recess TR.

As shown in FIG. 2, recess TR has a rectangular cross-sectional shape. The cross-sectional shape of recess TR is not limited to this. For example, as shown in FIG. 4, the cross-sectional shape of recess TR may be curved toward first surface FS.

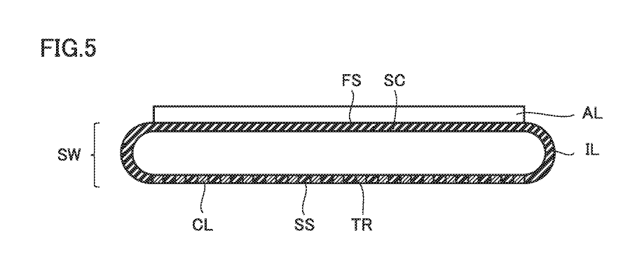

As shown in FIG. 5, a conductive film CL may be formed in recess TR. Conductive film CL is formed in contact with support substrate semiconductor SC. Conductive film CL may be a film having electrical conductivity. For example, for conductive film CL, polycrystalline Si or the like doped with an impurity is used.

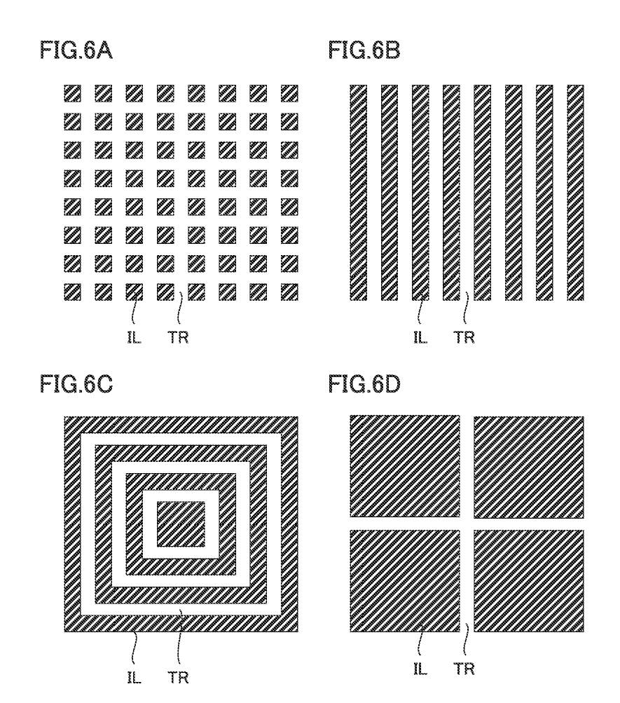

The shape in plan view and the position of insulating film IL on the second surface SS side are not particularly limited. As shown in FIG. 6A to FIG. 6D, insulating film IL on the second surface SS side may be divided by recess TR into a plurality of sections as seen in plan view (as seen in the direction perpendicular to second surface SS). More specifically, a plurality of recesses TR may intersect each other to thereby divide insulating film IL on the second surface SS side into a plurality of sections.

For example, as shown in FIG. 6A, each of a plurality of sections into which insulating film IL on the second surface SS side is divided by recess(es) TR has a square shape. As shown in FIG. 6B, each of a plurality of sections into which insulating film IL on the second surface SS side is divided by recess(es) TR may have a stripe shape. As shown in FIG. 6C, insulating film IL on the second surface SS side may be divided into a plurality of sections by recess(es) TR formed in the shape of concentric rectangles. As shown in FIG. 6D, insulating film IL on the second surface SS side may be divided into a plurality of sections by recess(es) TR formed in the shape of a cross.

Recess TR preferably has a linear shape as seen in plan view. Preferably, a plurality of recesses TR intersect each other at a predetermined angle. The angle is preferably 90° or more. Namely, each of a plurality of sections into which insulating film IL on the second surface SS side is divided by recess(es) TR preferably has a shape of a polygon having angles which are each 90° or more as seen in plan view.

Each of a plurality of sections into which insulating film IL on the second surface SS side is divided by recess(es) TR may have a shape other than the polygonal shape. For example, each of a plurality of sections into which insulating film IL on the second surface SS side is divided by recess(es) TR may have a curved shape.

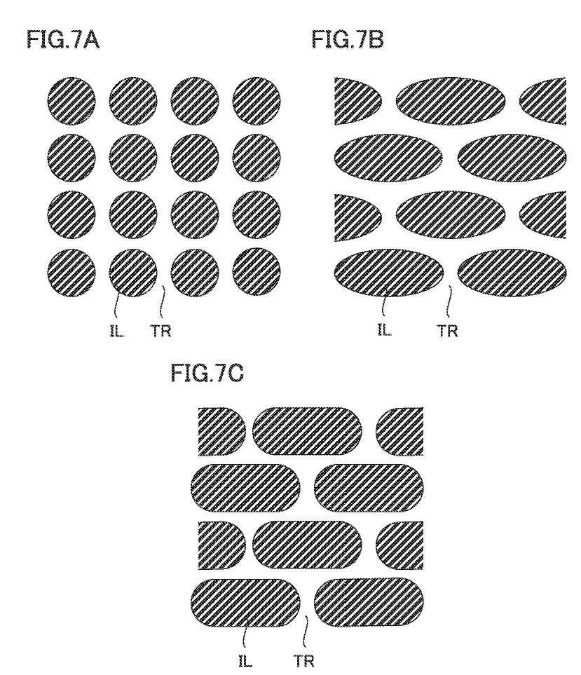

As shown in FIG. 7A, each of a plurality of sections into which insulating film IL on the second surface SS side is divided by recess(es) IR may have a circular shape as seen in plan view. Each of a plurality of sections into which insulating film IL on the second surface SS side is divided by recess(es) TR may have an elliptical shape as seen in plan view as shown in FIG. 7B. Each of a plurality of sections into which insulating film IL on the second surface SS side is divided by recess(es) TR may have an oval shape as seen in plan view as shown in FIG. 7C.

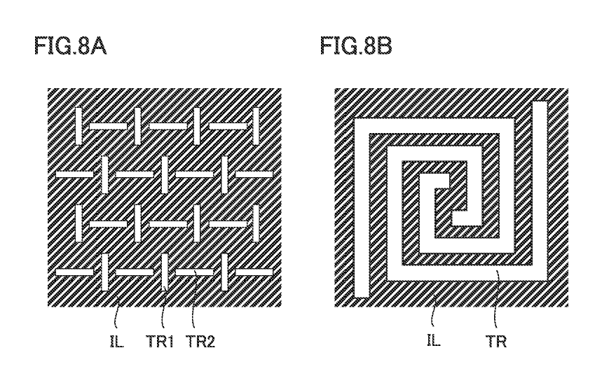

Insulating film IL on the second surface SS side may not be divided by recess TR into a plurality of sections. Insulating film IL on the second surface SS side may be formed to be continuous as seen in plan view. For example, as shown in FIG. 8A, recesses TR1 may be formed in a first direction and recesses TR2 may be formed in a second direction orthogonal to the first direction so that recess TR1 and recess TR2 are not integrated into a single recess, as seen in plan view. As shown in FIG. 8B, recesses TR may be formed in the shape of a swirl as seen in plan view. These recesses for example allow insulating film IL on the second surface SS side to be formed continuously.

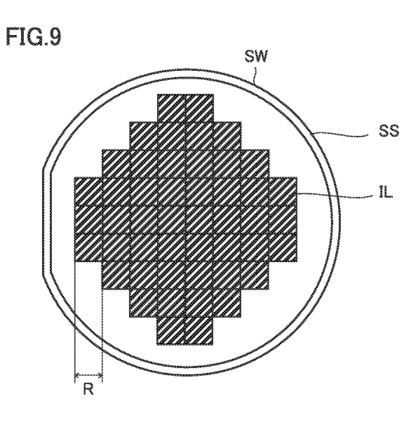

Insulating film IL on the second surface SS side may have a shape as seen in plan view in which the shape as shown in any of FIGS. 6A to 8B is repeated as shown in FIG. 9. The cycle of repetition R corresponds to the size of a region (a region of 25 mm×25 mm for example) which can be processed in one step of photolithography or the like.

In the following, a method for manufacturing a semiconductor wafer in accordance with an embodiment will be described.

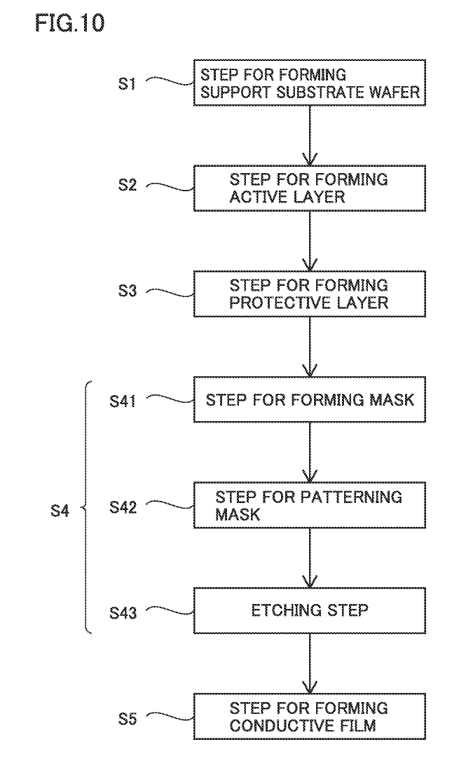

As shown in FIG. 10, the method for manufacturing a semiconductor wafer in accordance with the embodiment includes a step S1 for forming a support substrate semiconductor wafer, a step S2 for forming an active layer, and a step S4 for forming a recess. The method for manufacturing a semiconductor wafer in the embodiment may also include a step S3 for forming a protective layer and a step S5 for forming a conductive film.

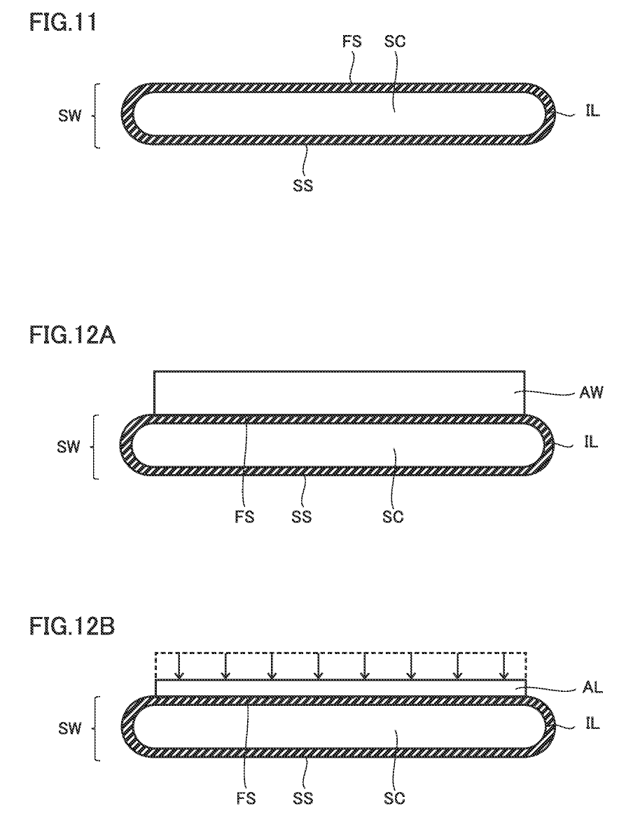

In step S1 for forming a support substrate semiconductor wafer, support substrate semiconductor wafer SW is formed. More specifically, in step S1 for forming a support substrate semiconductor wafer, insulating film IL is formed on support substrate semiconductor SC as shown in FIG. 11. Insulating film IL is formed by thermal oxidation for example of support substrate semiconductor SC.

In step S2 for forming an active layer, active layer AL is formed on first surface FS of support substrate semiconductor wafer SW. In step S2 for forming an active layer, initially an active layer semiconductor water AW is bonded onto first surface FS of support substrate semiconductor wafer SW as shown in FIG. 12A.

Next, as shown in FIG. 12B, active layer semiconductor wafer AW has a surface on the support substrate semiconductor wafer SW side and a surface opposite thereto, and this opposite surface is polished. In this way, active layer AL is formed on first surface FS of support substrate semiconductor wafer SW.

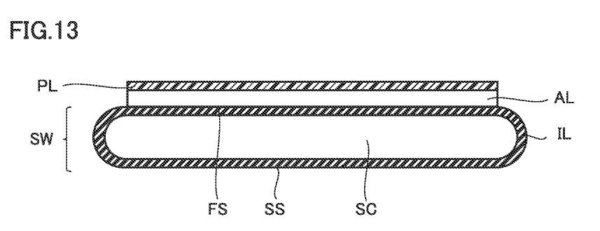

In step S3 for forming a protective layer, a protective layer PL is formed as shown in FIG. 13. Protective layer PL is formed on active layer AL. Protective layer PL is formed of a photoresist or the like, for example. After step S3 for forming a protective layer is performed, the semiconductor wafer in the embodiment is turned upside down. Accordingly, active layer AL is protected.

In step S4 for forming a recess, recess TR is formed in second surface SS of support substrate semiconductor wafer SW. As shown in FIG. 10, step S4 for forming a recess includes, for example, a step S41 for forming a mask, a step S42 for patterning the mask, and an etching step S43.

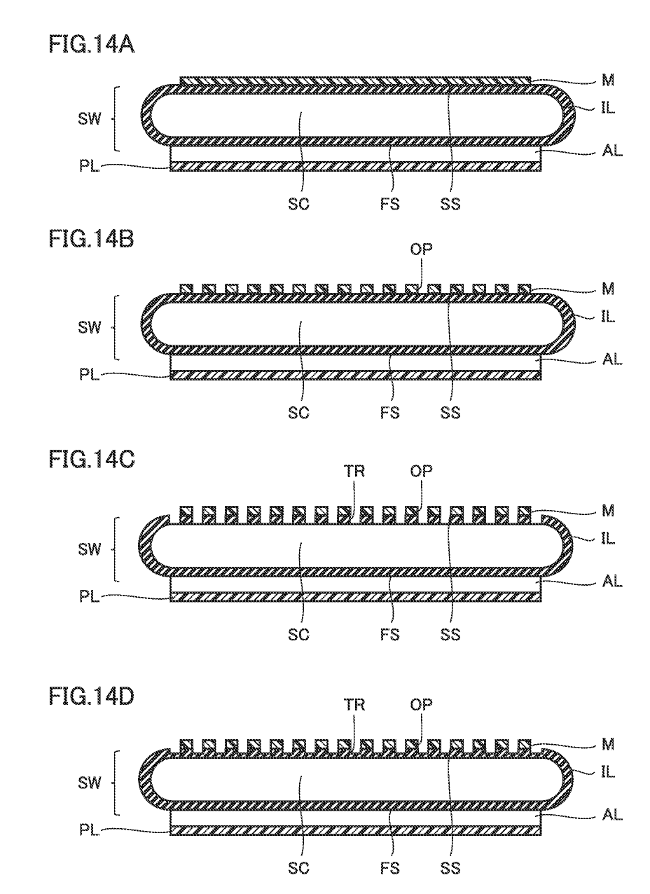

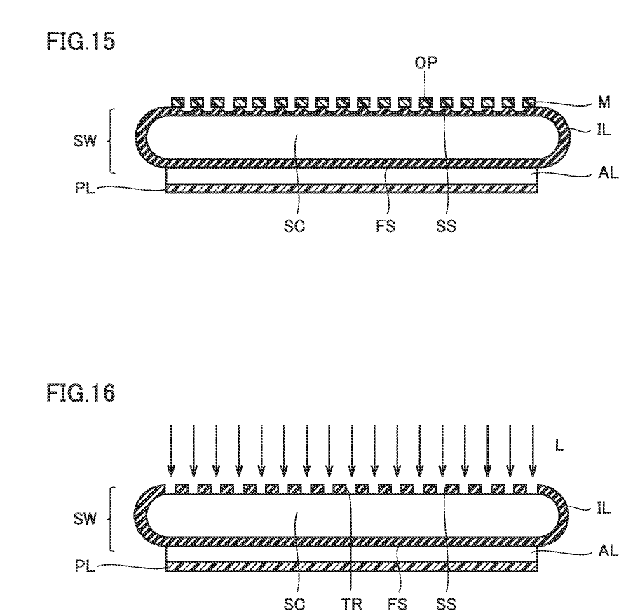

As shown in FIG. 14A, in step S41 for forming a mask, a mask M is formed on second surface SS of support substrate semiconductor wafer SW. Mask M is formed by applying a light-sensitive organic material such as photoresist for example onto second surface SS by means of spin coating or the like.

As shown in FIG. 14B, in step S42 for patterning the mask, mask M is patterned. Mask M is patterned by partially removing mask M by means of photolithography, for example. Accordingly, an opening OP is formed in mask M. From opening OP, insulating film IL on the second surface SS side is exposed.

Mask M is preferably patterned so that the ratio of mask M covering insulating film IL on the second surface SS side is 50% or more and less than 100%.

As shown in FIG. 14C, in etching step S43, recess TR is formed. Recess TR is formed by anisotropic etching such as RIE (Reactive Ion Etching) of insulating film IL on the second surface SS side. This etching is performed on the portion exposed from opening OP. This etching is performed until recess TR extends through insulating film IL on the second surface SS side (until support substrate semiconductor SC is exposed). This etching may be stopped as shown in FIG. 14D before recess TR extends through insulating film IL on the second surface SS side. After etching step S43, mask M is removed by plasma treatment, treatment with a chemical solution, or the like.

The etching performed in etching step S43 is not limited to the anisotropic etching such as RIE. For example, in etching step S43, isotropic etching such as wet etching may be performed. Accordingly, as shown in FIG. 15, recess TR having a cross-sectional shape which is curved toward first surface FS is formed.

Step S4 for forming a recess is not limited to the above-described steps. For example, as shown in FIG. 16, in step S4 for forming a recess, a laser beam L may be applied onto insulating film IL on the second surface SS side to form recess TR.

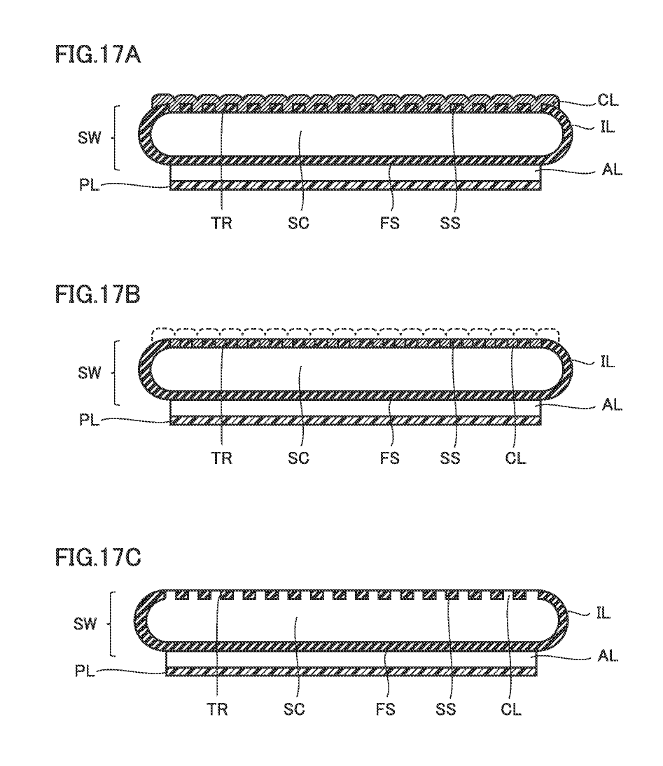

In step S5 for forming a conductive film, conductive film CL is formed. Conductive film CL is formed in recess TR. For forming conductive film CL, initially conductive film CL is deposited on support substrate semiconductor SC which is exposed from recess TR and on insulating film IL on the second surface SS side as shown in FIG. 17A. Conductive film CL is deposited by means of CVD (Chemical Vapor Deposition), sputtering, or the like. After this, as shown in FIG. 17B, conductive film CL protruding from recess TR is removed by means of CMP (Chemical Mechanical Polishing), etching, or the like, to thereby form conductive film CL in recess TR.

Step S5 for forming a conductive film is not limited to the above-described step. In step S5 for forming a conductive film, conductive film CL may be formed for example by epitaxial growth of conductive film CL on support substrate semiconductor SC which is exposed from recess TR, as shown in FIG. 17C.

In the following, effects of the semiconductor wafer in accordance with the embodiment will be described through comparison with a comparative example.

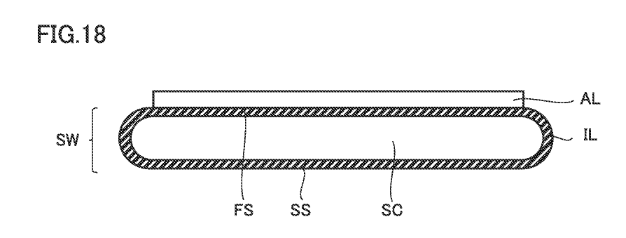

As shown in FIG. 18, a semiconductor wafer in the comparative example includes a support substrate semiconductor wafer SW and an active layer AL. Support substrate semiconductor wafer SW has a first surface FS and a second surface SS. Active layer AL is formed on first surface FS. Support substrate semiconductor wafer SW includes a support substrate semiconductor SC and an insulating film IL. Insulating film IL is formed on a first surface FS side and a second surface SS side of support substrate semiconductor SC.

However, the semiconductor wafer in the comparative example differs from the semiconductor wafer in the embodiment in that the semiconductor wafer in the comparative example does not have recess TR formed in insulating film IL on the second surface SS side of the support substrate semiconductor wafer. Namely, the area of insulating film IL of first surface FS is equal to the area of insulating film IL of second surface SS.

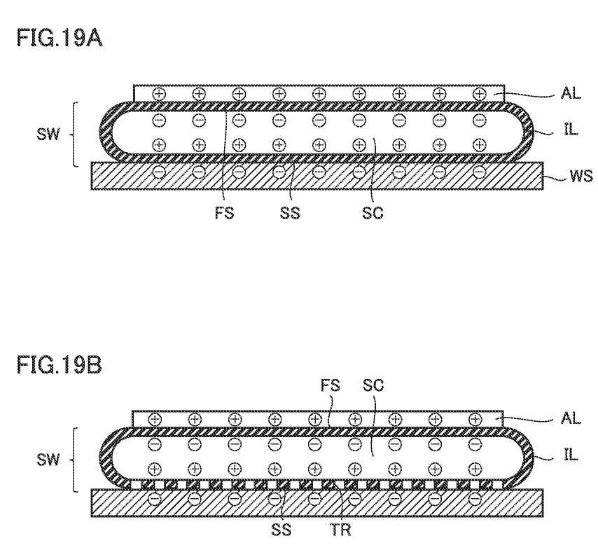

As shown in FIG. 19A, active layer AL of the semiconductor wafer in the comparative example is usually positively charged by ion implantation or the like in active layer AL. Active layer AL and support substrate semiconductor SC are electrically conductive and insulating film IL is electrically insulating. Therefore, active layer AL, support substrate semiconductor SC, and insulating film IL between active layer AL and support substrate semiconductor SC (namely insulating film IL on the first surface FS side) form a capacitor. As a result, positively-charged active layer AL causes negative charge to be induced in the first surface FS side of support substrate semiconductor SC. As the negative charge is induced in the first surface FS side of support substrate semiconductor SC, positive charge is induced in the second surface SS side of support substrate semiconductor SC.

A work stage WS is usually made of metal. Therefore, support substrate semiconductor SC, work stage WS, and insulating film IL between support substrate semiconductor SC and work stage WS (namely insulating film IL on the second surface SS side) form a capacitor. As a result, the positive charge in the second surface SS side of support substrate semiconductor SC causes negative charge to be induced in work stage WS.

The negative charge induced in work stage WS and the positive charge induced in the second surface SS side of support substrate semiconductor SC cause an attractive force to be generated between work stage WS and the semiconductor water in the comparative example. By the attractive force between second surface SS and work stage WS, the semiconductor wafer in the comparative example is adsorbed to work stage WS.

As shown in FIG. 19B, the semiconductor wafer in the embodiment is also adsorbed to work stage WS by the attractive force between work stage WS and the semiconductor wafer. However, regarding the semiconductor wafer in the embodiment, the area of insulating film IL of second surface SS is smaller than the area of insulating film IL of first surface FS.

The attractive force between second surface SS and work stage WS increases with increase of the area of insulating film IL of second surface SS. Therefore, regarding the semiconductor wafer in the embodiment, the attractive force is smaller as compared with the semiconductor wafer in the comparative example. Accordingly, the semiconductor wafer in the embodiment can be easily moved away from work stage WS and transported to the next stage.

As seen from the above, the semiconductor water in the embodiment enables prevention of the semiconductor wafer from being adsorbed to a work stage, transport arm, or the like, by means of simple measures.

The material (SiO₂, for example) used for insulating film IL has a smaller thermal expansion coefficient than that of the material (Si, for example) used for support substrate semiconductor SC. Therefore, as insulating film IL is formed by thermal oxidation or the like on the first surface FS side and the second surface SS side and thereafter cooling is done, tensile residual stress from insulating film IL is exerted on support substrate semiconductor SC.

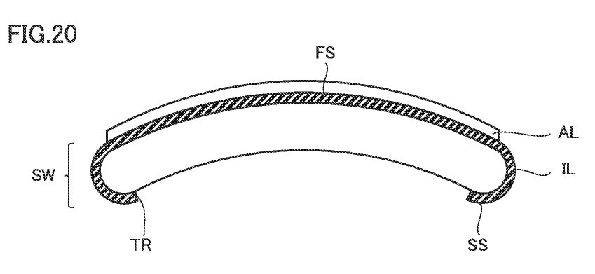

In the case where insulating film IL on the second surface SS side is removed, this residual stress is released from the second surface SS side. This may cause support substrate semiconductor wafer SW to be warped as shown in FIG. 20.

However, regarding the semiconductor wafer in the embodiment, in the case where insulating film IL on the second surface SS side has an area which is 0.5 times or more and less than once as large as the area of the insulating film on the first surface FS side, for example, the removal of a part of insulating film IL on the second surface SS side releases the residual stress to a limited extent only. As a result, the warp of support substrate semiconductor wafer SW can be suppressed.

Moreover, in the case as shown in FIG. 2 where the semiconductor wafer in the embodiment has recess TR and recess TR extends through insulating film IL on the second surface SS side, support substrate semiconductor SC is exposed. Charge accumulated in support substrate semiconductor SC is easily released from this exposed portion into the atmosphere. Accordingly, the semiconductor wafer in the embodiment is adsorbed more weakly to a work stage or the like.

Moreover, as shown in FIGS. 3 and 4, in the case where recess TR of the semiconductor wafer in the embodiment does not extend through insulating film IL on the second surface SS side, insulating film IL on the second surface SS side also remains in the portion where recess TR is formed. In this case, the partial removal of insulating film IL on the second surface SS side releases the residual stress to a limited extent. Therefore, in the case of the semiconductor wafer in the embodiment, warp of support substrate semiconductor wafer SW can be suppressed.

Moreover, as shown in FIG. 5, in the case where recess TR in the semiconductor wafer in the embodiment extends through insulating film IL on the second surface SS side and conductive film CL is formed in recess TR, charge accumulated in support substrate semiconductor SC is easily released through conductive film CL to a work stage or the like. Therefore, in the case of the semiconductor wafer in the embodiment, the semiconductor water is more weakly adsorbed to the work stage or the like.

Moreover, as shown in FIGS. 6B and 6D, in the case where recess TR of the semiconductor wafer in the embodiment has a linear shape as seen in plan view, it is easy to produce a photomask for photolithography which is to be used for forming recess TR. Therefore, in the case of the semiconductor wafer in the embodiment, the process for manufacturing support substrate semiconductor wafer SW can be simplified.

Moreover, as shown in FIG. 6A, in the case where insulating film IL on the second surface SS side of the semiconductor wafer in the embodiment is divided by recess(es) TR into a plurality of sections each having a shape of a polygon as seen in plan view and each angle of the polygon is 90° or more, stress concentration is less likely to occur in the end of insulating film IL on the second surface SS side. Therefore, in the case of the semiconductor wafer in the embodiment, separation of insulating film IL on the second surface SS side from support substrate semiconductor SC can be suppressed.

Moreover, as shown in FIGS. 7A to 7C, in the case where insulating film IL on the second surface SS side of the semiconductor wafer in the embodiment is divided by recess(es) TR into a plurality of sections each having a curved shape as seen in plan view, stress concentration is less likely to occur in the end of insulating film IL on the second surface SS side. Therefore, in the case of the semiconductor wafer in the embodiment, separation of insulating film IL on the second surface SS side from support substrate semiconductor SC can be suppressed.

Moreover, as shown in FIGS. 8A and 8B, in the case where insulating film IL on the second surface SS side is continuously formed as seen in plan view, namely in the case where recess TR is surrounded by insulating film IL as seen in plan view, the removal of insulating film IL on the second surface SS side releases the residual stress to a limited extent only. Therefore, in the case of the semiconductor wafer in the embodiment, warp of support substrate semiconductor water SW can be suppressed.

Moreover, as shown in FIG. 4, in the case where recess TR of the semiconductor wafer in the embodiment has a cross-sectional shape which is curved toward first surface FS, recess TR can be formed by wet etching at a high etching rate, or the like. Therefore, in this case, the production efficiency of the semiconductor water can be improved.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor wafer comprising:
a support substrate semiconductor wafer having a first surface and a second surface opposite to the first surface and including a support substrate semiconductor and an insulating film which is formed on a first surface side and a second surface side of the support substrate semiconductor, an area of the insulating film of the second surface being smaller than an area of the insulating film of the first surface; and
an active layer formed on the first surface.

2. The semiconductor water according to claim 1, wherein the area of the insulating film of the second surface is 0.5 times or more and less than once as large as the area of the insulating film of the first surface.

3. The semiconductor wafer according to claim 1, wherein
the insulating film on the second surface side includes a recess extending from the second surface toward the first surface.

4. The semiconductor wafer according to claim 3, wherein
a cross-sectional shape of the recess is rectangular.

5. The semiconductor wafer according to claim 3, wherein
a cross-sectional shape of the recess is curved toward the first surface.

6. The semiconductor wafer according to claim 3, wherein
the recess extends through the insulating film on the second surface side.

7. The semiconductor wafer according to claim 6, further comprising a conductive film formed in the recess and being in contact with the support substrate semiconductor.

8. The semiconductor wafer according to claim 3, wherein
the recess has a linear shape as seen in plan view.

9. The semiconductor wafer according to claim 6, wherein
the insulating film on the second surface side is divided by the recess into a plurality of sections as seen in plan view, and
a shape in plan view of each of the plurality of sections is a polygon, and each angle of the polygon is 90° or more.

10. The semiconductor wafer according to claim 6, wherein
the insulating film on the second surface side is divided by the recess into a plurality of sections as seen in plan view, and
a shape in plan view of each of the plurality of sections includes a curved shape.

11. The semiconductor wafer according to claim 6, wherein
the insulating film on the second surface side is continuous as seen in plan view.

12. The semiconductor water according to claim 3, wherein
the recess does not extend through the insulating film on the second surface side.

13. A method for manufacturing a semiconductor wafer, comprising:
forming a support substrate semiconductor wafer having a first surface and a second surface opposite to the first surface and including a support substrate semiconductor and an insulating film which is formed on a first surface side and a second surface side of the support substrate semiconductor;
forming an active layer on the first surface; and
forming a recess in the insulating film on the second surface side, the recess extending in a direction from the second surface to the first surface.

14. The method for manufacturing a semiconductor wafer according to claim 13, wherein
the forming a recess includes:
forming a mask having an opening on the second surface; and
etching the insulating film on the second surface side through the opening.

15. The method for manufacturing a semiconductor wafer according to claim 14, wherein
the mask covers 50% or more and less than 100% of the insulating film on the second surface side as seen in plan view.

16. The method for manufacturing a semiconductor wafer according to claim 15, wherein
the etching is wet etching.

17. The method for manufacturing a semiconductor wafer according to claim 13, wherein
the forming a recess includes applying a laser beam onto the second surface.

18. The method for manufacturing a semiconductor wafer according to claim 13, wherein
the forming a recess is performed to allow the recess to extend through the insulating film on the second surface side and allow the support substrate semiconductor to be exposed from the recess, and
the method further comprises forming a conductive film located in the recess and being in contact with the support substrate semiconductor.

19. The method for manufacturing a semiconductor wafer according to claim 13, further comprising forming a protective layer on the active layer.
